(19) United States
(12) Patent Application Publication
(10) Pub. No.: US 2020/0357842 A1
(43) Pub. Date: Nov. 12, 2020

(54) IMAGE SENSOR MODULE HAVING PROTECTIVE STRUCTURE THAT BLOCKS INCIDENT LIGHT TO ARRIVE AT BONDING WIRES AND PADS

(71) Applicant: OmniVision Technologies, Inc., Santa Clara, CA (US)

(72) Inventors: Wei-Feng Lin, Hsinchu City (TW); Chi-Chih Huang, Taoyuan City (TW); Yu-Mei Su, Taipei City (TW)

(73) Assignee: OmniVision Technologies, Inc., Santa Clara, CA (US)

(21) Appl. No.: 16/937,759

(22) Filed: Jul. 24, 2020

Related U.S. Application Data
(63) Continuation of application No. 15/654,271, filed on Jul. 19, 2017.

(51) Int. Cl. H01L 27/146; H04N 1/03; H04N 5/225

(52) U.S. Cl. CPC H01L 27/14689; H01L 27/14625; H04N 1/0308; H01L 27/14636; H04N 5/2253; H01L 27/14698; H04N 5/2257; H01L 27/14618; H01L 27/14685

(57) ABSTRACT

An image sensor module comprises: a substrate having a first side and second side, the first side being an opposite of the second side, an image sensor attached to the first side of the substrate, bonding wires to bond the image sensor to pads on the first side of the substrate, a protective structure disposed on the first side of the substrate surrounding the image sensor, the bonding wires, and the pads, the protective structure having a dam and a lid, a cover glass disposed on the protective structure, and a set of solder balls attached to the second side of the substrate.

### CROSS-REFERENCE TO RELATED APPLICATION

This application is a continuation application of U.S. patent application Ser. No. 15/654,271, filed Jul. 19, 2017.

### FIELD OF THE INVENTION

This invention relates to an image sensor module, and more specifically relates to an image sensor module having protective structure.

### BACKGROUND OF THE INVENTION

Recently, camera modules are mounted on smart phones, automobiles, medical devices, and so on. With the developments of technology, the resolution of the camera increases, while the size of the camera reduces significantly. The camera modules are manufactured by using typically, but not limited to, complementary metal oxide semiconductor (CMOS) image sensors. Incident light transmitted through the lens or lens module is focused on the image sensor forming the image of the object.

The image sensor is wire bonded to pads on a substrate. For some camera modules, the wires and the pads of the substrate may be close to the light sensing area of the image sensor. Some of incident light may be reflected by the wires and/or the pads generating unwanted flare on the image detected by the image sensor.

Accordingly, wire bonded image sensors that generate no flare on the detected image are demanded.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 shows an example of conventional camera module.

FIG. 2 shows an example of conventional image sensor module.

FIG. 3 shows an exemplary image sensor module according to an embodiment of the present invention.

FIG. 4A shows a top perspective view of an exemplary protective structure comprising a surrounding dam and a circular lid, according to an embodiment of the present invention.

FIG. 4B shows a bottom perspective view of exemplary protective structure of FIG. 4A, according to an embodiment of the present invention.

FIG. 5A shows an exemplary image sensor module according to an embodiment of the present invention.

FIG. 5B shows the wall of hole of the lid forming an angle α less than 90° with the surface of the lid, according to an embodiment of the present invention.

FIGS. 6A-6F show an exemplary method for making image sensor module according to an embodiment of the present invention.

FIG. 7A shows a top perspective view of an exemplary singulated protective structure comprising a surrounding dam and a square lid, according to an embodiment of the present invention.

FIG. 7B shows a bottom perspective view of exemplary protective structure of FIG. 7A, according to an embodiment of the present invention.

FIG. 8 shows an exemplary camera module according to an embodiment of the present invention.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention.

### DETAILED DESCRIPTION

In the following description, numerous specific details are set forth in order to provide a thorough understanding of the present invention. It will be apparent, however, to one having ordinary skill in the art that the specific detail need not be employed to practice the present invention. In other instances, well-known materials or methods have not been described in detail in order to avoid obscuring the present invention.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment. Furthermore, the particular features, structures or characteristics may be combined in any suitable combinations and/or sub-combinations in one or more embodiments.

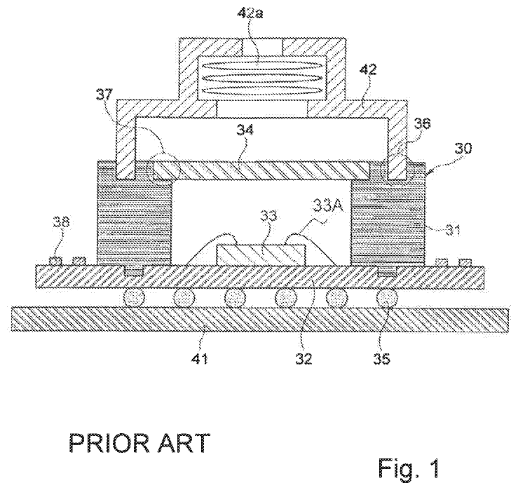

FIG. 1 shows an example of conventional camera module comprising an image sensor module and a lens module disposed on the image sensor module. The image sensor module comprises an image sensor 33, bonding wires 33A to bond image sensor 33 to a substrate 32, a holder 31 to surround image sensor 33, a cover glass or IR filter 34 to enclose image sensor 33, and solder balls 35 to electrically coupled image sensor 33 to a main substrate 41 through wires 33A.

The lens module comprises a housing 42 and a plurality of lenses 42a. The lens module is disposed on the image sensor module, so incident light transmitted through the lenses 42a forms an image of an object on image sensor 33.

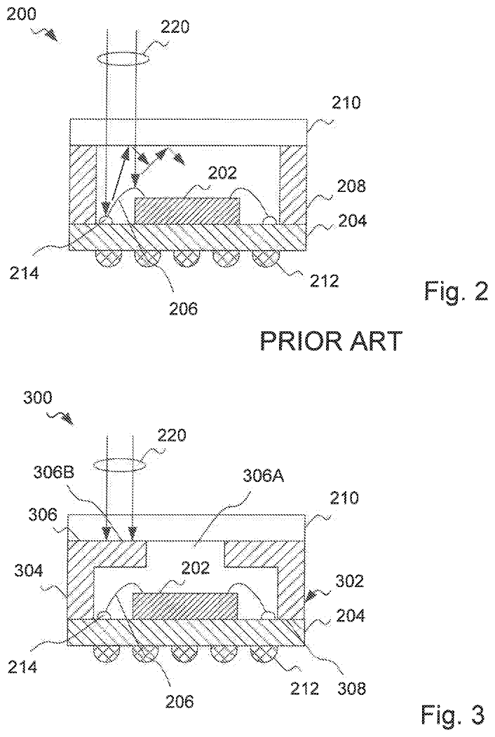

FIG. 2 shows an example of conventional image sensor module 200, which may be an image sensor module included in the conventional camera module of FIG. 1. Image sensor module 200 comprises an image sensor 202 disposed on a first side of a substrate 204. Image sensor 202 is wire bonded by wires 206 to pads 214 on the first side of substrate 204. A dam 208 disposed on the first side of substrate 204 surrounds image sensor 202, bonding wires 206 and pads 214. A cover glass 210 disposed on dam 208 encloses image sensor 202. A plurality of solder balls 212 is attached to a second side, which is an opposite to the first side, of substrate 204 for electrically coupling image sensor 202 to outside image sensor module 200.

An incident light 220 transmitted through a lens module (not shown) may arrive on wire 206 and pad 214 on substrate 204, and may be reflected toward a light sensing area of image sensor 202 generating flare on an image detected by image sensor 202. The generated flare is not wanted and should be reduced or eliminated.

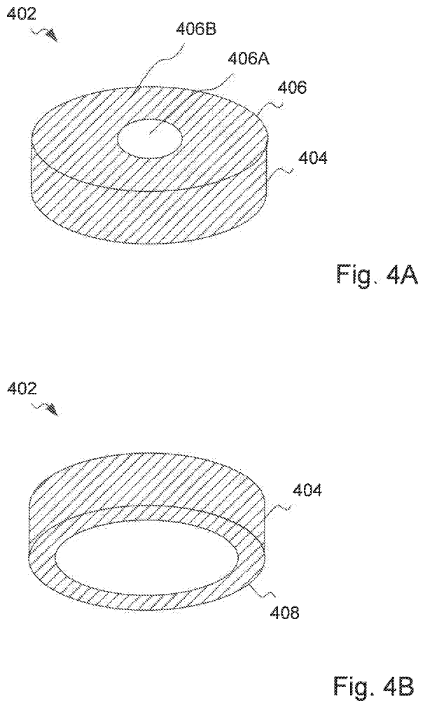

FIG. 3 shows an exemplary image sensor module 300 according to an embodiment of the present invention. A protective structure 302 replaces dam 208 of image sensor module 200 of FIG. 2. Protective structure 302 comprises a dam 304 and a lid 306, which are made of the same material and fabricated as an integrated part. Lid 306 cannot be separated from dam 304. Lid 306 has a hole 306A to transmit the incident light transmitted through the lens module (not shown) to arrive at image sensor 202, and a non-transparent part 306B surrounding hole 306A to cover wires 206 and pad 214 from an incident light 220.

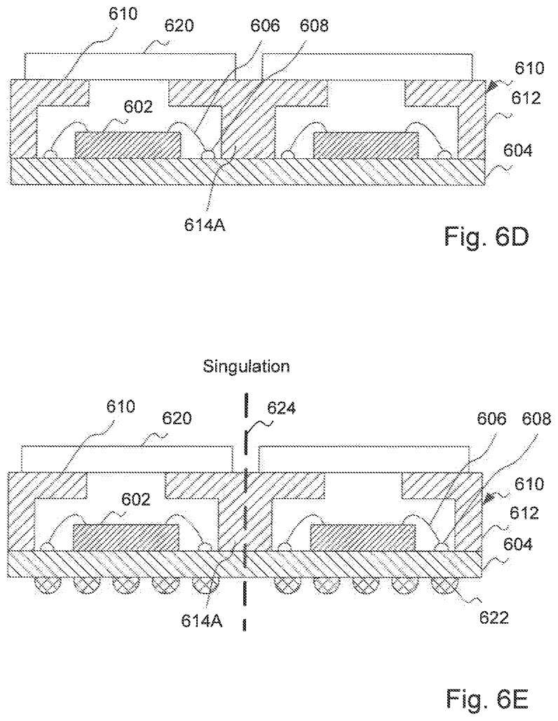

Image sensor module 300 comprises an image sensor 202 attached to a first side of a substrate 204. Image sensor 202 may be a CMOS image sensor. Image sensor 202 is wire bonded by wires 206 to pads 214 on the first side of substrate 204. Protective structure 302 disposed on the first side of substrate 204 surrounds image sensor 202, bonding wires 206 and pads 214. A bottom 308 of dam 304 of protective structure 302 is attached to the first side of substrate 204. A cover glass 210 disposed on lid 306 of protective structure 302 encloses image sensor 202. Cover glass 210, protective structure 302, and substrate 204 enclose image sensor 202. It is appreciated that cover glass 210 needs to cover hole 306A, and may be as large as protective structure 302 (shown in FIG. 3) or may be smaller than protective structure 302 (shown in FIG. 6F). Cover glass 210 is attached to lid 306 of protective structure 302. Cover glass 210 may be an IR filter. A plurality of solder balls 212 are attached to a second side of substrate 202 for electrically coupling image sensor 202 to outside image sensor module 300. The second side is opposite to the first side. Solder balls 212 are electrically coupled to pads 214.

Parts of an incident light 220 transmitted through the lens module (not shown) are blocked by non-transparent part 306B of lid 306 of protective structure 302. Incident light 220 cannot arrive on wire 206 and pad 214 on substrate 202, thus no light is reflected toward the light sensing area of image sensor 202 and no flare is generated on an image detected by image sensor 202.

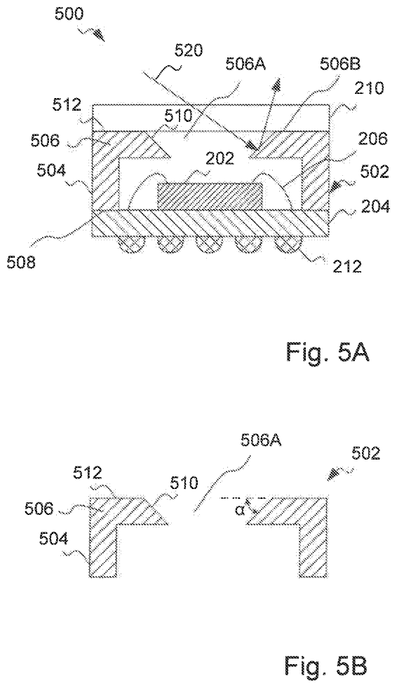

FIG. 4A shows a top perspective view of an exemplary protective structure 402 comprising a surrounding dam 404 and a circular lid 406, according to an embodiment of the present invention. Protective structure 402 may be protective structure 302 of FIG. 3. Circular lid 406 further comprises circular hole 406A and a non-transparent part 406B surrounding circular hole 406A. Hole 406A may be positioned at the center of lid 406.

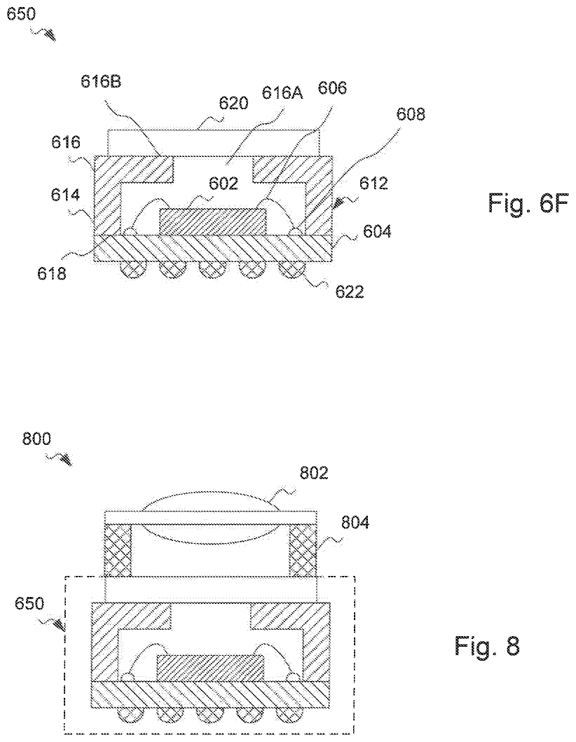

FIG. 4B shows a bottom perspective view of exemplary protective structure 402, according to an embodiment of the present invention. FIG. 4B shows a bottom 408 of surrounding dam 404. Protective structure 402 has a circular cross-section as indicated by circular lid 406. It is appreciated that the cross-section of protective structure 402 and lid 406 may be square (shown in FIGS. 7A and 7B), rectangular, an ellipse, or any shape.

Protective structure 302 may be made of black or light absorptive materials. Scattered light inside protective structure 302 may be absorbed by the material of protective structure 302. Protective structure 302 may be fabricated using at least a mold or other methods such that surrounding dam 304 and lid 304 are inseparable parts of an integrated structure.

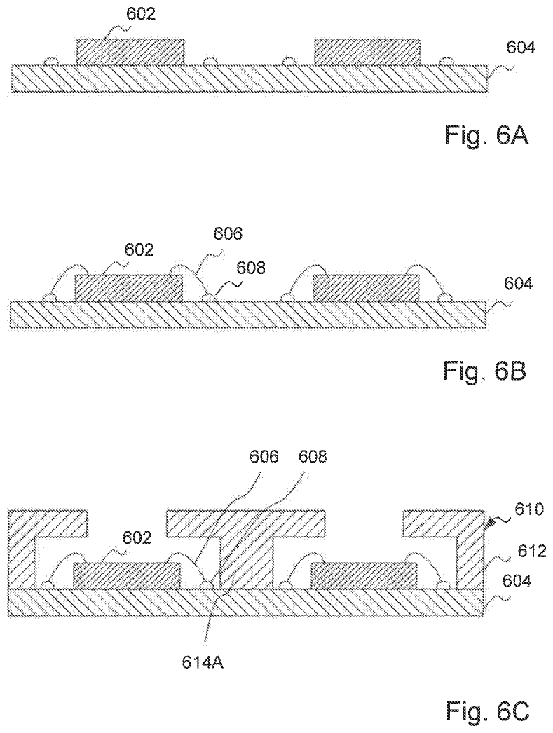

FIG. 5A shows an exemplary image sensor module 500 according to an embodiment of the present invention. FIG. 5A is similar to FIG. 3 except a protective structure 502 replaces protective structure 302 in FIG. 3. Similar to protective structure 302, protective structure 502 comprises a dam 504 and a lid 506, which are made of the same material and fabricated as an integrated part. Lid 506 cannot be separated from dam 504. Lid 506 has a hole 506A to transmit the incident light transmitted through the lens module (not shown) to arrive at image sensor 202, and a non-transparent part 506B surrounding hole 506A to block the incident light to arrive at wires 206 and pad 214. A bottom 508 of dam 504 of protective structure 502 is attached to the first side of substrate 204.

A wall 510 forming hole 506A of lid 506 may form an angle α less than 90° with a surface 512 of lid 506, as shown in FIG. 5B according to an embodiment of the present invention. In an embodiment, a may be less than 45°. An incident light 520 incident to wall 510 is reflected away from a light sensing area of image sensor 202 (see FIG. 5A). In this manner, image sensor module 500 further reduces flare generated by the reflection of incident light.

FIGS. 6A-6F show an exemplary method for making image sensor module 300 of FIG. 3 or image sensor module 500 of FIG. 5A according to an embodiment of the present invention. FIG. 6A shows a plurality of image sensors 602 are attached to a first side of substrate 604. Two image sensors are shown in FIG. 6A for illustration, however more than two image sensors may be attached to the first side of substrate 604, thus more than two image sensor modules can be made. FIG. 6B shows each image sensor 602 is wire bonded using wires 606 to pads 608 on the first side of substrate 604.

FIG. 6C shows that a unified structure 610 is disposed on the first side of substrate 604. Unified structure 610 comprises a plurality of inter-connected protective structures 612. Each protective structure 612 is shown in FIGS. 7A and 7B, according to an embodiment of the present invention. Each protective structure 612 may have a square or rectangular cross-section. Each protective structure 612 comprises a dam 614 and a lid 616. Dam 614 and lid 616 are inseparable forming an integrated part. Lid 616 has a hole 616A and a non-transparent part 616B surrounding hole 616A. Hole 616A may be circular, but may be square, rectangular, an ellipse, or any shape as well. Dam 614 has a bottom 618, which may be attached to the first side of substrate 604. Neighboring protective structures 612 have a common dam 614A as shown in FIG. 6C.

Unified structure 610 is pre-made prior to disposing on the first side of substrate 604. Unified structure 610 may be pre-made using at least a mold or by other methods. Unified structure 610 is made of light absorptive materials.

FIG. 6D shows that a piece of cover glass 620 is disposed on each protective structure 612 to enclose an image sensor 602 forming a unit of image sensor module. Multiple pieces of cover glass are disposed on unified structure 610. Each cover glass 620 is attached to lid 616 of each protective structure 612. FIG. 6E shows a set of solder balls 622 is attached to a second side of substrate 604 of each formed unit of image sensor module. The second side of substrate 604 is opposite to the first side of substrate 604.

After sets of solder balls 622 are attached to all units of image sensor module, substrate 604 and unified structure 612 attached to substrate 604 are singulated along a line 624 within common dam 614A to form a plurality of units of image sensor 650 as shown in FIG. 6E.

FIG. 6F shows a single unit of image sensor module 650 after singulated from a plurality of units of image sensor module on substrate 604, which are inter-connected by unified structure 610. Image sensor module 650 comprises image sensor 602 disposed on the first side of substrate 604. Image sensor 602 is wire bonded by wires 606 to pads 608 on the first side of substrate 604. Protective structure 612 is disposed on substrate surrounding image sensor 602, bonding wires 606, and pads 608. Cover glass 620 disposed on protective structure 612 encloses image sensor 602. Set of solder balls 622 is attached to substrate 604 for electrically coupling image sensor 602 to outside image sensor module 650.

Protective structure 612 comprises dam 614 and lid 616, which are made of the same material and fabricated as an integrated part. Lid 616 cannot be separated from dam 614. Bottom 618 of dam 614 of protective structure 612 is attached to the first side of substrate 604. Lid 616 has a hole 616A to transmit the incident light transmitted through the lens module (not shown) to arrive at image sensor 602, and a non-transparent part 616B surrounding hole 616A to block the incident light to arrive at wires 606 and pads 608.

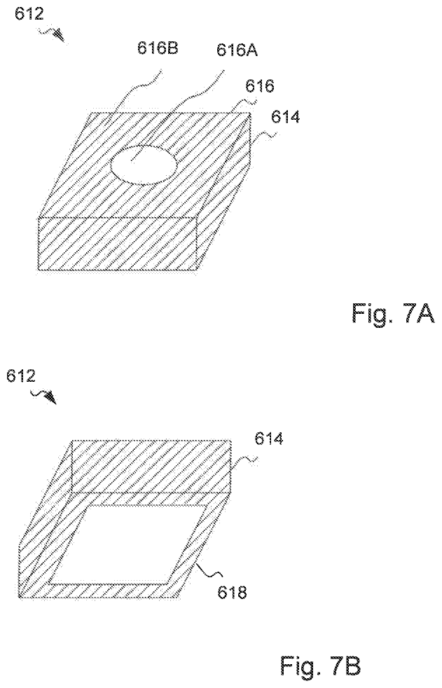

FIG. 8 shows an exemplary camera module 800 according to an embodiment of the present invention. Camera module 800 comprises image sensor module 650 of FIG. 6F, a lens system 802, and a spacer 804 disposed in between image sensor module 650 and lens system 802. Lens system 802 forms an image of an object on the image sensor of image sensor module 650.

While the present invention has been described herein with respect to the exemplary embodiments and the best mode for practicing the invention, it will be apparent to one of ordinary skill in the art that many modifications, improvements and sub-combinations of the various embodiments, adaptations and variations can be made to the invention without departing from the spirit and scope thereof.

The terms used in the following claims should not be construed to limit the invention to the specific embodiments disclosed in the specification and the claims. Rather, the scope is to be determined entirely by the following claims, which are to be construed in accordance with established doctrines of claim interpretation. The present specification and figures are accordingly to be regarded as illustrative rather than restrictive.

What is claimed is:

1. An image sensor module comprising:
a substrate having a first side and a second side, the first side being an opposite to the second side;
an image sensor attached to the first side of the substrate;
bonding wires to bond the image sensor to pads on the first side of the substrate;
a protective structure disposed on the first side of the substrate surrounding the image sensor, the bonding wires, and the pads;
the protective structure comprising a dam and a lid;
the lid comprising a hole and a non-transparent part to light surrounding the hole;
wherein the hole transmits incident light to arrive at the image sensor, and the non-transparent part blocks incident light to arrive at the bonding wires and the pads; and
a cover glass disposed on the protective structure;
wherein a bottom of the dam of the protective structure is attached to the first side of the substrate and the cover glass is attached to the lid of the protective structure;
and
wherein a wall forming the hole of the lid forms an angle α less than 90° with a surface of the lid.

2. The image sensor module of claim 1 further comprising:
a set of solder balls attached to the second side of the substrate.

3. The image sensor module of claim 1, wherein the protective structure is made of light absorptive materials.

4. The image sensor module of claim 3, wherein scatter light in the protective structure is absorbed by the protective structure.

5. The image sensor module of claim 1, wherein the dam and the lid are inseparable forming an integrated part.

6. The image sensor module of claim 1, wherein a is less than 45°.

7. The image sensor module of claim 1, wherein the image sensor is a CMOS image sensor.

8. A camera module comprising:
an image sensor module comprising:
a substrate having a first side and a second side, the first side being an opposite to the second side;
an image sensor attached to the first side of the substrate;
bonding wires to bond the image sensor to pads on the first side of the substrate;
a protective structure disposed on the first side of the substrate surrounding the image sensor, the bonding wires, and the pads;
the protective structure comprising a dam and a lid;
the lid comprising a hole and a non-transparent part to light surrounding the hole;
wherein the hole transmits incident light to arrive at the image sensor, and the non-transparent part blocks incident light to arrive at the bonding wires and the pads;
and
a cover glass disposed on the protective structure;
wherein a bottom of the dam of the protective structure is attached to the first side of the substrate and the cover glass is attached to the lid of the protective structure;
a lens system; and
a spacer disposed in between the image sensor module and the lens system;
and
wherein a wall forming the hole of the lid forms an angle α less than 90° with a surface of the lid.

9. The camera module of claim 8 further comprising:
a set of solder balls attached to the second side of the substrate.

10. The camera module of claim 8, wherein the protective structure is made of light absorptive materials.

11. The camera module of claim 10, wherein scatter light in the protective structure is absorbed by the protective structure.

12. The camera module of claim 8, wherein the dam and the lid are inseparable forming an integrated part.

13. The camera module of claim 8, wherein a is less than 45°.

14. The camera module of claim 8, wherein the image sensor is a CMOS image sensor.
